(19) United States
(12) Patent Application Publication
(10) Pub. No.: US 2025/0028257 A1
(43) Pub. Date: Jan. 23, 2025

(54) SEMICONDUCTOR PROCESS APPARATUS

(71) Applicant: SAMSUNG ELECTRONICS CO., LTD., Suwon-si (KR)

(72) Inventors: Kyoungwhan Oh, Suwon-si (KR); Dahae Lee, Suwon-si (KR); Eunhee Jeang, Suwon-si (KR); Chulmin Cho, Suwon-si (KR); Kyungwon Kang, Suwon-si (KR)

(21) Appl. No.: 18/436,744

(22) Filed: Feb. 8, 2024

(30) Foreign Application Priority Data
Jul. 17, 2023 (KR) 10-2023-0092345

(51) Int. Cl. G03F 7/00; G03F 7/20

(52) U.S. Cl. CPC G03F 7/70991; G03F 7/2004; G03F 7/70033; G03F 7/7015; G03F 7/702; G03F 7/70716; G03F 7/70958

(57) ABSTRACT

A semiconductor process apparatus includes a light generator configured to output extreme ultraviolet (EUV) light having an EUV wavelength band, a mask stage configured to seat a mask reflecting the EUV light output from the light generator, a light-receiving optical unit including a plurality of mirrors generating output light by reflecting the EUV light reflected from the mask, at least one of the plurality of mirrors including a mirror body and a reflective layer attached to a surface of the mirror body, a power supply configured to apply a bias voltage to the reflective layer, and a substrate stage configured to seat a substrate to be irradiated with the output light.

### CROSS-REFERENCE TO RELATED APPLICATION(S)

This application claims priority to and the benefit of Korean Patent Application No. 10-2023-0092345, filed in the Korean Intellectual Property Office on Jul. 17, 2023, the disclosure of which is incorporated herein by reference in its entirety.

### BACKGROUND

Semiconductor processes include photo processes, etching processes, deposition processes, and the like for forming a plurality of layers on a substrate, in which a plurality of patterns may be formed on the plurality of respective layers. As the line width and spacing of a plurality of patterns are gradually refined, photolithography processes using light of a relatively short wavelength band, for example, Extreme Ultra Violet (EUV) light, has been proposed. A semiconductor process apparatus performing a photolithography process using EUV light may include a plurality of mirrors that reflect the EUV light. However, when EUV light is irradiated only on a partial area of at least one of the plurality of mirrors, deformation may occur in the mirror, which may decrease the yield of the photolithography process.

### SUMMARY

In general, in some aspects, the present disclosure is directed to a semiconductor process apparatus having improved yield of semiconductor processing, by which a graphene layer may be formed capable of reducing temperature imbalance according to the pattern of irradiated EUV light in at least one of a plurality of mirrors included in the semiconductor process apparatus performing a photolithography process using the EUV light.

According to some aspects of the present disclosure, a semiconductor process apparatus includes a lighting unit (light generator) configured to output EUV light having an EUV wavelength band, a mask stage on which a mask reflecting the EUV light output from the lighting unit is seated, a light-receiving optical unit (optical light receiver) including a plurality of mirrors generating output light by reflecting the EUV light reflected from the mask, at least one of the plurality of mirrors including a mirror body and a reflective layer attached to a surface of the mirror body, a power supply configured to apply a bias voltage to the reflective layer, and a substrate stage on which a substrate irradiated with the output light is seated. In some implementations, the reflective layer includes a plurality of silicon layers, a plurality of molybdenum layers alternately stacked with the plurality of silicon layers, and at least one graphene layer, in which the graphene layer includes a base region including graphene, and a plurality of pads attached to the base region and to which the bias voltage is applied.

According to some aspects of the present disclosure, a semiconductor process apparatus includes a mask stage on which a mask is seated, a substrate stage on which a substrate is seated, a lighting unit (light generator) configured to output EUV light having an EUV wavelength band to the mask, and a light-receiving optical unit (optical light receiver) including a plurality of mirrors reflecting the EUV light reflected from the mask and enabling the EUV light to be incident to the substrate, at least one of the plurality of mirrors including a mirror body and a reflective layer attached to a surface of the mirror body. In some implementations, the reflective layer includes a plurality of silicon layers, a plurality of molybdenum layers alternately stacked with the plurality of silicon layers, and at least one graphene layer.

According to some aspects of the present disclosure, a semiconductor process apparatus includes a lighting unit (light generator) configured to output EUV light, a mask stage on which a mask reflecting the EUV light output from the lighting unit is seated, a substrate stage on which a substrate receiving the EUV light reflected from the mask is seated, and a light-receiving optical unit (optical light receiver) disposed between the mask stage and the substrate stage and including a plurality of mirrors reflecting the EUV light reflected from the mask. In some implementations, at least one of the plurality of mirrors includes a mirror body and a reflective layer attached to a surface of the mirror body, and the reflective layer includes a plurality of first layers, a plurality of second layers, and at least one third layer. In some implementations, the plurality of first layers, the plurality of second layers, and the third layer are formed of different materials, and the plurality of first layers and the plurality of second layers are alternately stacked, in which a thickness of the third layer is less than a thickness of each of the plurality of first layers and the plurality of second layers.

### BRIEF DESCRIPTION OF DRAWINGS

Exemplary implementations will be more clearly understood from the following detailed description, taken in conjunction with the accompanying drawings.

FIG. 1 is a schematic diagram of an exemplary semiconductor process apparatus according to some implementations.

FIG. 2 is a diagram illustrating an exemplary operation of a semiconductor process apparatus according to some implementations.

FIGS. 3A and 3B are diagrams illustrating an exemplary operation of a semiconductor process apparatus according to some implementations.

FIG. 4 is a schematic diagram illustrating an exemplary mirror included in a semiconductor process apparatus according to some implementations.

FIGS. 5 to 9 are schematic views illustrating an exemplary stacked structure of a reflective layer included in a mirror in a semiconductor process apparatus according to some implementations.

FIGS. 10A to 10C are schematic diagrams illustrating an exemplary operation of a semiconductor process apparatus according to some implementations.

FIG. 11 is a schematic diagram of an exemplary semiconductor process apparatus according to some implementations.

FIGS. 12 to 15 are schematic diagrams illustrating an exemplary operation of a semiconductor process apparatus according to some implementations.

FIGS. 16 to 20 are schematic diagrams illustrating an exemplary operation of a semiconductor process apparatus according to some implementations.

FIGS. 21 and 22 are schematic diagrams illustrating an exemplary operation of a semiconductor process apparatus according to some implementations.

FIG. 23 is a schematic diagram illustrating an exemplary stacked structure of a reflective layer included in a mirror in a semiconductor process apparatus according to some implementations.

FIGS. 24 and 25 are schematic views illustrating an exemplary operation of a semiconductor process apparatus according to some implementations.

### DETAILED DESCRIPTION

Hereinafter, exemplary implementations will be described in detail with reference to the accompanying drawings.

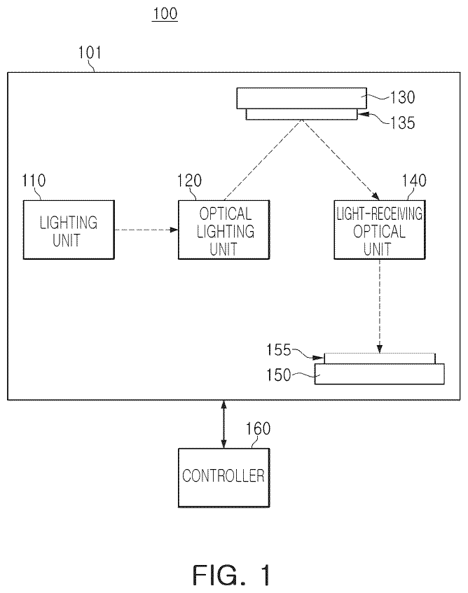

FIG. 1 is a schematic diagram illustrating an exemplary semiconductor process apparatus according to some implementations. In FIG. 1, an exemplary semiconductor process apparatus 100 includes a device for performing a photolithography process, and may include a lighting unit (light generator) 110, an optical lighting unit (light generator) 120, a mask stage 130, a light-receiving optical unit (optical light receiver) 140, a wafer stage 150, and a controller 160.

The lighting unit 110 may be configured to generate and emit EUV light having a high energy density within a wavelength range of several nanometers to several tens of nanometers. In some implementations, the lighting unit 110 may generate and output EUV light having a high energy density in a 13.5 nm wavelength band, and may include a plasma-based light source or a synchrotron radiation light source. For example, a light source included in the lighting unit 110 may output EUV light using a plasma. The light source irradiates a high-power laser to droplets formed of one of materials, such as tin, lithium, and xenon, and may operate in the Laser-Produced Plasma (LPP) method that generates plasma, operate in a discharge-produced plasma (DPP) method, or operate in Master Oscillator Power Amplifier (MOPA) method. The high-power laser collides with droplets supplied by the droplet supply unit to form plasma, and therefore, an illumination mirror and a collector for re-concentrating EUV light formed by the plasma may be included in the lighting unit 110. The collector is configured to function as a type of reflector and may be located close to the droplet in order to increase re-condensing efficiency. Energy density of the EUV light output from the lighting unit 110 may be increased by the lighting mirror and the collector.

The optical lighting unit 120 may include a plurality of mirrors. In the exemplary semiconductor process apparatus 100, the optical lighting unit 120 may include two or three mirrors. However, the number of mirrors included in the optical lighting unit 120 is not necessarily limited to two or three. The illumination optical unit 120 may be configured to transfer EUV light emitted from the lighting unit 110 toward the mask stage 130. Here, the EUV light emitted from the lighting unit 110 may be reflected by mirrors included in the optical lighting unit 120 and may be incident to the mask 135 seated on the mask stage 130. In some implementations, a mask 135 may be a reflective mask that includes a reflective region, as well as a non-reflective region and/or an intermediate reflective region. In some implementations, the mask 135 may include a reflective multilayer film for reflecting extreme ultraviolet light on a substrate formed of a low thermal expansion coefficient material (LTEM), such as quartz, and an absorption layer pattern formed on a reflective multilayer film, etc. In some implementations, the reflective multilayer film may have a structure in which layers formed of different materials are stacked. In some implementations, the absorption layer may be formed of TaN, TaNO, TaBO, Ni, Au, Ag, C, Te, Pt, Pd, Cr, or the like. However, the material of the absorption layer is not limited to the above-mentioned materials, and the portion of the absorption layer may correspond to the non-reflective area and/or the intermediate reflective area described above.

The mask 135 may reflect EUV light incident through the optical lighting unit 120 and cause it to be incident to the light-receiving optical unit 140. The light-receiving optical unit 140 may be configured as an imaging optical system that is disposed between the mask stage 130 and the wafer stage 150. In some implementations, the EUV light passing through the optical lighting unit 120 may be structured according to a pattern formed of a reflective multilayer film and an absorption layer on a substrate in the mask 135 and may be incident to the light-receiving optical unit 140.

The EUV light may be structured to include at least second-order diffracted light based on the pattern on the mask 135. The structured EUV light is incident to the light-receiving optical unit 140 while retaining the information of the pattern form included in the mask 135, and the wafer 155 seated on the wafer stage 150 may be irradiated through the light-receiving optical unit 140 so that an image corresponding to the pattern shape included in the mask 135 is formed. In some implementations, structured EUV light is irradiated onto a photoresist layer applied over the wafer 155, and a predetermined pattern may be formed on the photoresist layer. However, according to some implementations, the structured EUV light passing through the light-receiving optical unit 140 may be incident to a process target other than the wafer 155.

The EUV light reflected by the mask 135 and passed through the light-receiving optical unit 140 may be incident with a predetermined slope with respect to the upper surface of the wafer 155. In some implementations, the light-receiving optical unit 140 may adjust the traveling path of the EUV light so that the EUV light is incident with the upper surface of the wafer 155 at an incident angle of about 6 degrees.

The mask 135 may be disposed on the mask stage 130, and the wafer 155 may be disposed on the wafer stage 150. In some implementations, the mask stage 130 and the wafer stage 150 may be controlled by the controller 160. In the initial state, in which the mask 135 and the wafer 155 are respectively seated on the mask stage 130 and the wafer stage 150, when the upper surface of each of the mask 135 and the wafer 155 is defined as an x-y plane, each of the mask stage 130 and the wafer stage 150 may be moved by the controller 160. In some implementations, the controller 160 may be configured to rotate each of the mask stage 130 and the wafer stage 150 on the x-y plane based on the z-axis, or may be rotated on the y-z plane or the x-z plane based on any one axis of the x-y plane. By the movement of the mask stage 130 and/or the wafer stage 150 as described above, the mask 135 and/or the wafer 155 may move or rotate along the x-axis, y-axis, and z-axis in a three-dimensional space.

The light-receiving optical unit 140 may include a plurality of mirrors. Each of the plurality of mirrors included in the light-receiving optical unit 140 may include a mirror body and a reflective layer attached to a surface of the mirror body. As described above, the EUV light passing through the optical lighting unit 120 and reflected by the mask 135 is structured and enter the light-receiving optical unit 140, and each of the plurality of mirrors may reflect the structured EUV light.

Since EUV light is structured and incident, during the exemplary process, in at least one mirror of the plurality of mirrors, EUV light may be irradiated only on a partial area. Accordingly, the temperature may rise only in some areas irradiated with EUV light, and due to physical deformation occurring in the mirror, characteristics of EUV light reflected from the mirror may be unintentionally changed.

In some implementations, to reduce the temperature imbalance as described above, the reflective layer may include at least one graphene layer. In some implementations, the reflective layer may include a plurality of silicon layers, a plurality of molybdenum layers alternately stacked with the plurality of silicon layers, and at least one graphene layer. Here, the position where the graphene layer is disposed and the number of graphene layers may be variously modified depending on the implementation.

The graphene layer may have relatively high thermal conductivity compared to the silicon layer and the molybdenum layer. When the structured EUV light is irradiated only onto a portion of the reflective layer included in the mirror, the temperature increase due to the irradiation of EUV light may be easily transferred to the entire area of the reflective layer, and the temperature imbalance of the mirror may be reduced.

In some implementations, the graphene layer may include a base region formed of graphene and a plurality of pads attached to the base region. The plurality of pads may be connected to a power supply included in the controller 160 or the like. The power supply refers to the pattern of the structured EUV light so that only the region not irradiated with EUV light during the process in the mirror is selectively heated. A voltage may be applied to some selected pads among the plurality of pads. Accordingly, the temperature imbalance according to the position of the mirror may be effectively resolved and the yield of the process may be improved.

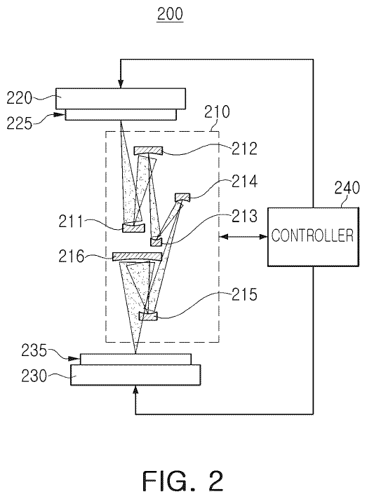

FIG. 2 is a diagram illustrating an exemplary operation of a semiconductor process apparatus according to some implementations. In FIG. 2, a semiconductor process apparatus 200 according to some implementations may include a light-receiving optical unit (optical light receiver) 210, a mask stage 220, a wafer stage 230, a controller 240, and the like. A mask 225 may be seated on the mask stage 220, and a wafer 235 may be seated on the wafer stage 230.

The light-receiving optical unit 210 includes a plurality of mirrors 211-216 configured to reflect EUV light reflected from the mask 225, and EUV light reflected by the plurality of mirrors 211 to 216 may be incident on the wafer 235. The controller 240 may be configured to operate the semiconductor process apparatus 200 by adjusting positions and attitudes of the plurality of mirrors 211 to 216 together with the mask stage 220 and the wafer stage 230 such that EUV light reflected from the mask 225 is incident on the wafer 235.

Each of the plurality of mirrors 211 to 216 may include a mirror body and a reflective layer disposed on a surface of the mirror body. The reflective layer may be a layer formed on the surface of the mirror body for the purpose of increasing the reflectance of extreme ultraviolet light in each of the plurality of mirrors 211 to 216, and in some implementations, may include a plurality of first layers and a plurality of second layers formed of different materials and alternately stacked. The first layer and the second layer are formed of materials having different refractive indices, and in some implementations, the first layer may be formed of silicon and the second layer may be formed of molybdenum.

In FIG. 2, at least some of the plurality of mirrors 211 to 216 may have different sizes. In at least one of the plurality of mirrors 211 to 216, EUV light may be reflected after being irradiated only onto a partial area of the mirror, and not onto the front surface of the mirror. Accordingly, the temperature of the partial region to which the EUV light is irradiated may be higher than the temperature of the remaining region to which the EUV light is not irradiated. The shape of the mirror may be deformed due to the temperature difference, and unexpected aberrations may occur in the EUV light reflected from the mirror, and as a result, the yield of the semiconductor process performed in the semiconductor process apparatus 200 may decrease.

In some implementations, in the reflective layer included in at least one of the plurality of mirrors 211 to 216, which is expected to undergo shape deformation due to a temperature difference, at least one third layer formed of a material different from the first and second layers may be added. In some implementations, the third layer may be formed of a material having a thickness smaller than that of each of the first and second layers and having higher thermal conductivity than materials constituting the first and second layers. Accordingly, the thermal conductivity of the entire reflective layer may be improved by the third layer, and the temperature difference appearing in the mirror may be significantly reduced. In some implementations, the third layer may be formed of graphene having high thermal conductivity.

When the graphene layer is included in the reflective layer, even when extreme ultraviolet light is irradiated and reflected only onto a portion of the mirror, heat generated by EUV light irradiated onto a partial area of the mirror may be effectively transferred to the front surface of the mirror. Accordingly, the temperature imbalance caused by irradiation of extreme ultraviolet light only upon a portion of the mirror may be reduced, and as a result, the shape deformation of the mirror may be significantly reduced.

In some implementations, the graphene layer included in the reflective layer may include a base region formed of graphene and a plurality of pads attached to the base region. A power supply is connected to the plurality of pads, and the power supply may include a power circuit configured to output a bias voltage, and may be included in the controller 240.

When a bias voltage is supplied to some selected pads among a plurality of pads, heat may be generated by a resistance component of the base region between the selection pads. In some implementations, heat generated by the bias voltage may be generated only in a partial region defined between the selection pads instead of the entire base region. Accordingly, in consideration of the pattern of EUV light radiated to the mirror, a region not directly irradiated with EUV light in the graphene layer included in the reflective layer of the mirror may be pre-heated with a bias voltage, as a result, temperature imbalance may be significantly reduced and shape deformation of the mirror may be prevented.

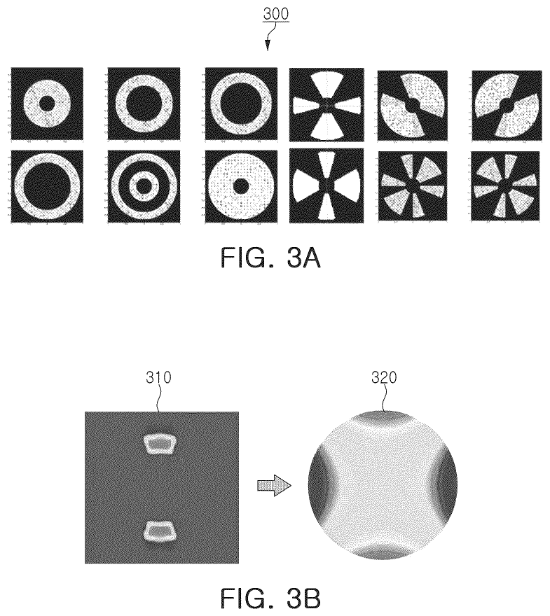

FIGS. 3A and 3B are diagrams illustrating an exemplary operation of a semiconductor process apparatus according to some implementations. In FIGS. 3A and 3B a pattern of EUV light 300 output by a lighting unit (light generator) is included in a semiconductor process apparatus and an aberration 320 appears in a mirror 310 during a semiconductor process. As illustrated in FIGS. 3A and 3B, the EUV light 300 output by the lighting unit may have a predetermined pattern on a plane perpendicular to the optical axis, in which EUV light may be irradiated only onto a partial area of the mirror 310. Since EUV light is radiated only onto a portion of the mirror 310, the temperature of some areas irradiated with EUV light may be higher than that of other areas. Accordingly, the shape of the mirror 310 may be physically deformed, and an aberration 320 may occur in the mirror 310, as illustrated in FIGS. 3A and 3B. Due to the aberration 320 generated in the mirror 310, the yield of the exemplary semiconductor process may decrease.

In some implementations, the aberration 320 generated in the mirror 310 due to unbalanced extreme ultraviolet light irradiation may be significantly reduced by adding a graphene layer to the reflective layer disposed on the surface of the mirror 310. Accordingly, a decrease in the yield of the semiconductor process may be prevented.

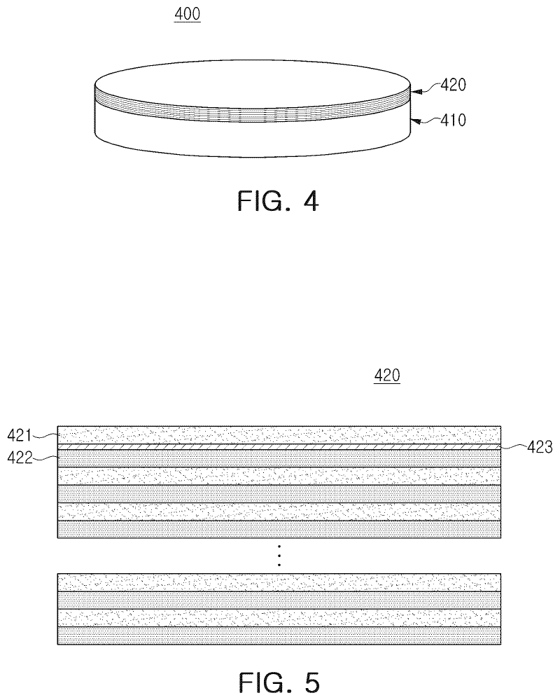

FIG. 4 is a diagram simply illustrating an exemplary mirror included in a semiconductor process apparatus according to some implementations. In FIG. 4, a mirror 400 included in a semiconductor process apparatus according to some implementations may include a mirror body 410 and a reflective layer 420 disposed on a surface of the mirror body 410. The reflective layer 420 is disposed on a surface on which EUV light is irradiated from the mirror body 410 and then reflected. In some implementations, the reflective layer 420 may include a plurality of layers.

In FIG. 4, the mirror 400 may be one of a plurality of mirrors included in the light-receiving optical unit disposed on a path through which EUV light reflected from the mask proceeds to the wafer. The reflective layer 420 may be attached to the surface of the mirror body 410 to improve the reflectance of EUV light and may include a plurality of silicon layers, a plurality of molybdenum layers, and at least one graphene layer. In some implementations, a plurality of silicon layers and a plurality of molybdenum layers included in the reflective layer 420 are alternately stacked, and a pair of Mo/Si layers including one silicon layer and one molybdenum layer may be included in the reflective layer 420 in several tens, for example, 40 to 50.

FIGS. 5 to 9 are schematic views illustrating an exemplary stacked structure of a reflective layer included in a mirror in a semiconductor process apparatus according to some implementations. In FIG. 5, the reflective layer 420 may include a plurality of silicon layers 421, a plurality of molybdenum layers 422, and a graphene layer 423. In some implementations, the upper surface of the graphene layer 423 is in contact with the lower surface of the silicon layer 421, and the lower surface of the graphene layer 423 may contact the upper surface of the molybdenum layer 422. The graphene layer 423 may be disposed between the silicon layer 421 located at the top among the plurality of silicon layers 421 and the molybdenum layer 422 located at the top among the plurality of molybdenum layers 422.

A thickness of the graphene layer 423 may be smaller than a thickness of the silicon layer 421 and a thickness of the molybdenum layer 422. In some implementations, the sum of the thicknesses of the silicon layer 421 and the molybdenum layer 422 adjacent to each other in the stacking direction may have a value close to half of 13.5 nm, which is a wavelength band of EUV light. In some implementations, the sum of the thicknesses of one silicon layer 421 and one molybdenum layer 422 contacting each other may be 6.5 nm to 7.5 nm, and the thickness of the graphene layer 423 may be 0.2 nm to 0.5 nm.

In some implementations, a heating layer made of molybdenum disilicide (MoSi₂) may be further disposed between the silicon layer 421 and the molybdenum layer 422 adjacent to each other in the stacking direction. The heating layer may be a layer intentionally inserted between the silicon layer 421 and the molybdenum layer 422 by a deposition process or the like. Accordingly, reflection efficiency of the reflective layer 420 may be improved by adding the heating layer.

A thickness of the heating layer may be smaller than the respective thicknesses of the silicon layer 421 and the molybdenum layer 422. In some implementations, when a heating layer is added, the sum of the thicknesses of the silicon layer 421 and the molybdenum layer 422 adjacent to each other in the stacking direction and the heating layer therebetween may have a value close to half of 13.5 nm, which is a wavelength band of EUV light.

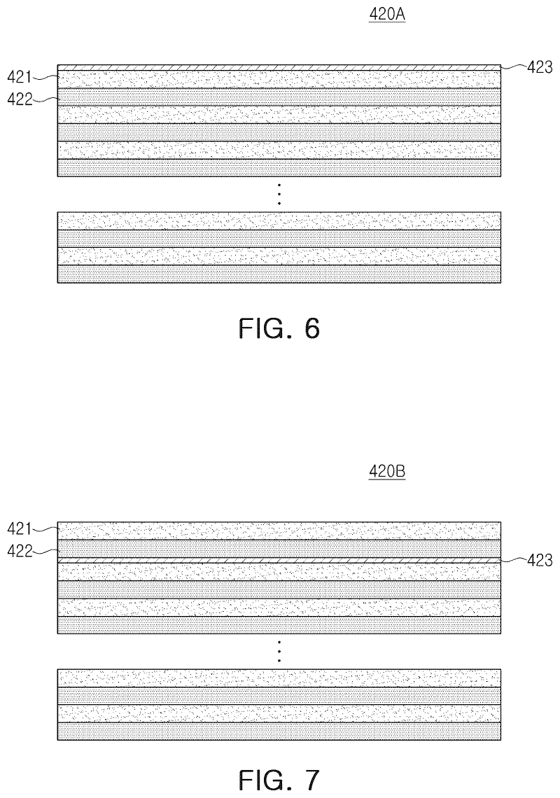

In FIG. 6, the reflective layer 420A may include a plurality of silicon layers 421, a plurality of molybdenum layers 422, and a graphene layer 423. In some implementations, the lower surface of the graphene layer 423 contacts the upper surface of the uppermost silicon layer 421, and the upper surface of the graphene layer 423 is exposed to the outside and may directly receive EUV light. In some implementations, the graphene layer 423 may be disposed on the lowermost side of the reflective layer 420A, in which one surface of the graphene layer 423 may contact the surface of the mirror body.

In FIG. 6, other characteristics except for the arrangement of the graphene layer 423 may be similar to those described above with reference to FIG. 5. In some implementations, the sum of the thicknesses of one silicon layer 421 and one molybdenum layer 422 contacting each other in the stacking direction may have a value close to half of 13.5 nm, which is a wavelength band of EUV light. Also, the thickness of the graphene layer 423 may be smaller than the thickness of the silicon layer 421 and the thickness of the molybdenum layer 422. In some implementations, a heating layer formed of a material having high heating characteristics, such as molybdenum disilicide, and may be additionally disposed between the silicon layer 421 and the molybdenum layer 422.

In FIG. 7, the reflective layer 420B may include a plurality of silicon layers 421, a plurality of molybdenum layers 422, and a graphene layer 423. In some implementations, the upper surface of the graphene layer 423 may contact the lower surface of the uppermost molybdenum layer 422, in which the graphene layer 423 may be disposed below the silicon layer 421 and the molybdenum layer 422 disposed on the top. In some implementations, other characteristics except for the arrangement of the graphene layer 423 may be similar to those described above with reference to FIG. 5.

In FIGS. 5 to 7, the reflective layers 420, 420A, and 420B are illustrated as including only one graphene layer 423, but in some implementations, two or more graphene layers 423 and 424 may be provided on the reflective layer 420C. In FIG. 8, among the plurality of silicon layers 421 and the plurality of molybdenum layers 422 included in the reflective layer 420C, a first graphene layer 423 may be disposed between the uppermost silicon layer 421 and the uppermost molybdenum layer 422. In some implementations, a second graphene layer 424 may be disposed under the uppermost molybdenum layer 422. In some implementations, the number of graphene layers 423 and 424 is not necessarily limited to two, and the number of graphene layers 423 and 424 may be three or more. In some implementations, the position where the graphene layers 423 and 424 are inserted is not limited to the example embodiments illustrated in FIGS. 5 to 8, and may be selected in various ways.

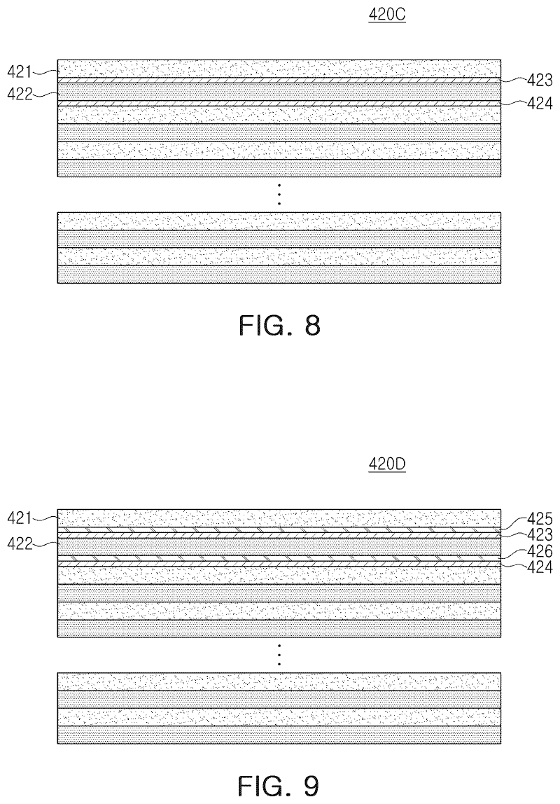

In FIG. 9, the reflective layer 420D may include a plurality of silicon layers 421, a plurality of molybdenum layers 422, graphene layers 423 and 424, and metal layers 425 and 426. The stacking order of the plurality of silicon layers 421, the plurality of molybdenum layers 422, and the graphene layers 423 and 424 may be similar to that described above with reference to FIG. 8. In some implementations, the reflective layer 420D may further include a first metal layer 425 and a second metal layer 426. Each of the first metal layer 425 and the second metal layer 426 may be layers provided to increase reflectance of the reflective layer 420D. In some implementations, a silicon layer 421 is disposed on the first metal layer 425 and a molybdenum layer 422 is disposed below. A molybdenum layer 422 may be disposed above the second metal layer 426 and a silicon layer 421 may be disposed below.

In some implementations, each of the first metal layer 425 and the second metal layer 426 may be plural. For example, the first metal layer 425 is disposed between the silicon layer 421 and the molybdenum layer 422 in the stacking direction, and the second metal layer 426 may be disposed between the molybdenum layer 422 and the silicon layer 421 in the stacking direction. The first metal layer 425 may be formed of yttrium or niobium. The second metal layer 426 may be formed of ruthenium.

In some implementations, the first graphene layer 423 is disposed between the first metal layer 425 and the molybdenum layer 422, and the second graphene layer 424 may be disposed between the second metal layer 426 and the silicon layer 421. For example, like the first graphene layer 423 and the second graphene layer 424, a thickness of each of the first metal layer 425 and the second metal layer 426 may be smaller than that of each of the silicon layer 421 and the molybdenum layer 422.

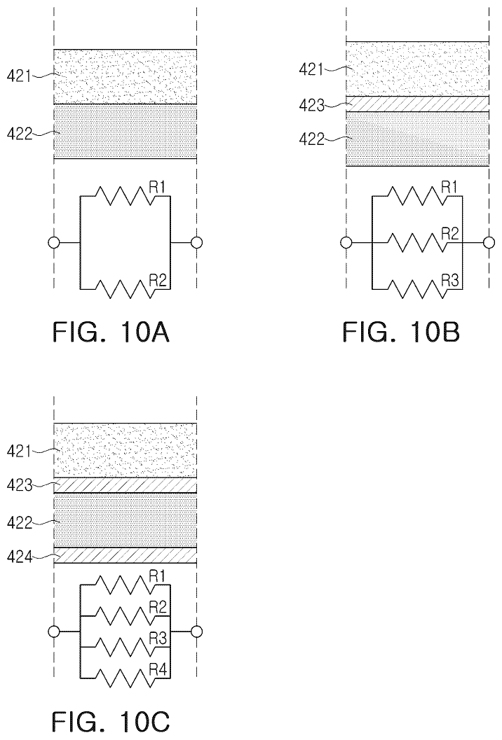

FIGS. 10A to 10C are schematic diagrams illustrating an exemplary operation of a semiconductor process apparatus according to some implementations. FIGS. 10A to 10C may be equivalent thermal circuits provided to describe thermal conductivity characteristics of a reflective layer attached to a mirror in a semiconductor process apparatus according to some implementations. In FIGS. 10A to 10C, thermal resistances R1-R4 representing thermal conductivity characteristics are illustrated. For convenience of explanation, it is assumed that the thickness and length of the silicon layer 421 and the molybdenum layer 422 are the same in each of FIGS. 10A to 10C.

FIG. 10A may be an equivalent heating circuit of a reflective layer including only the silicon layer 421 and the molybdenum layer 422. In FIG. 10A, the thermal resistance Rₜₒₜ₁ of the reflective layer including only the silicon layer 421 and the molybdenum layer 422 may be defined as in Equation 1 below. In Equation 1, Ksi and Kmo are the thermal conductivities of silicon and molybdenum, respectively, A is the thickness of the silicon layer and the molybdenum layer, and L may be the length of the silicon layer and the molybdenum layer.

$${R}_{tot 1} = \frac{A}{( Ksi + Kmo ) L} \qquad [ Equation 1 ]$$

FIG. 10B may be an equivalent heating circuit of a reflective layer including a silicon layer 421, a molybdenum layer 422, and a graphene layer 423. In FIG. 10B, the thermal resistance Rₜₒₜ₂ of the reflective layer including the silicon layer 421, the molybdenum layer 422, and the graphene layer 423 may be defined as Equation 2 below. For convenience of explanation, it is assumed that the thickness of the graphene layer 423 is 1/10 of the thickness of each of the silicon layer 421 and the molybdenum layer 422. In Equation 2, Kg may be the thermal conductivity of graphene.

$${R}_{tot 2} = \frac{A}{( Ksi + Kmo + 0.1 Kg ) L} \qquad [ Equation 2 ]$$

In some implementations, the thermal conductivity of graphene may be about 38 times that of silicon and about 35 times that of molybdenum. Accordingly, the thermal resistance Rₜₒₜ₂ of the reflective layer according to the implementation illustrated in FIG. 10B may be smaller than the thermal resistance Rₜₒₜ₁ of the reflective layer according to the implementation illustrated in FIG. 10A. By inserting the graphene layer 423, the thermal conductivity of the reflective layer may be improved. When EUV light is irradiated only upon a partial area of the mirror including the reflective layer, shape deformation due to temperature imbalance of the mirror may be significantly reduced and effectively suppress the occurrence of aberration of the mirror.

FIG. 10C may be an equivalent heating circuit of a reflective layer including a silicon layer 421, a molybdenum layer 422, and a plurality of graphene layers 423 and 424. In FIG. 10C, the thermal resistance Rₜₒₜ₃ of the reflective layer including the silicon layer 421, the molybdenum layer 422, and the graphene layers 423 and 424 may be defined as in Equation 3 below. For convenience of description, it is assumed that the thickness of each of the graphene layers 423 and 424 is 1/10 of the thickness of each of the silicon layer 421 and the molybdenum layer 422.

$${R}_{tot 3} = \frac{A}{( Ksi + Kmo + 0.2 Kg ) L} \qquad [ Equation 3 ]$$

In FIG. 10C, the thermal resistance Rₜₒₜ₃ of the reflective layer may be smaller than the thermal resistance Rₜₒₜ₁ of the reflective layer according to the implementation illustrated in FIG. 10A and the thermal resistance Rₜₒₜ₂ of the reflective layer according to the implementation illustrated in FIG. 10B. When EUV light is irradiated only upon a portion of the mirror including the reflective layer, shape deformation due to temperature imbalance of the mirror may be significantly reduced and effectively suppress the occurrence of aberration of the mirror.

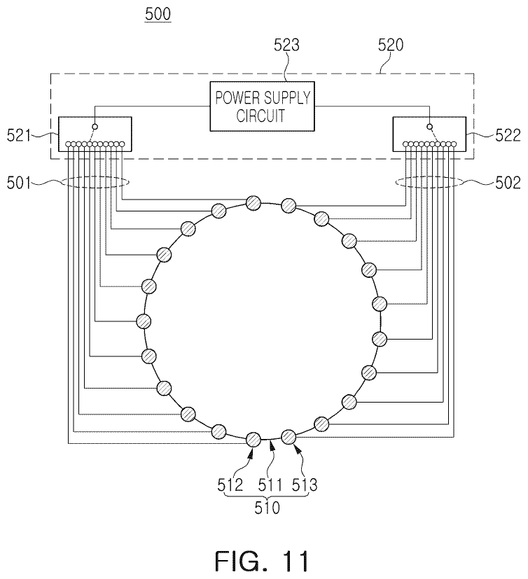

FIG. 11 is a schematic diagram of an exemplary semiconductor process apparatus according to some implementations. In FIG. 11, the semiconductor process apparatus 500 the reflective layer attached to the mirror includes a graphene layer 510, and the graphene layer 510 may include a base region 511 containing graphene and a plurality of pads 512 and 513 attached to the base region 511. The plurality of pads 512 and 513 are formed of a metal material and may be arranged along an edge of the base region 511. In some implementations, the plurality of pads 512 and 513 may be attached to locations other than the edges of the base region 511.

The plurality of pads 512 and 513 may include first pads 512 and second pads 513. The first pads 512 are connected to the first switch circuit 521 through a plurality of first wires 501, and the second pads 513 may be connected to the second switch circuit 522 through the plurality of second wires 502. The first switch circuit 521 and the second switch circuit 522 may provide the power supply 520 together with the power circuit 523.

The first switch circuit 521 may be configured to select one of the plurality of first wires 501 to determine a first selection pad among the first pads 512. In some implementations, the second switch circuit 522 may be configured to select one of the plurality of second wires 502 to determine a second selection pad among the second pads 513. The first switch circuit 521 includes a first multiplexer, and the second switch circuit 522 may include a second multiplexer.

When the first selection pad and the second selection pad are determined, the power circuit 523 may be configured to output a predetermined bias voltage. Accordingly, heat may be generated in a partial selection region defined between the first selection pad and the second selection pad in the base region 511 by the bias voltage. In some implementations, by selecting the selection region to which the bias voltage output from the power circuit 523 is applied, the first switch circuit 521 and the second switch circuit 522 are selected, and the temperature of a selected region that is a portion of the base region 511 may be increased. Accordingly, while EUV light having a predetermined pattern is being irradiated, a bias voltage is applied by selecting an area not irradiated with EUV light in the mirror including the reflective layer, thereby effectively resolving the temperature imbalance of the mirror including the reflective layer.

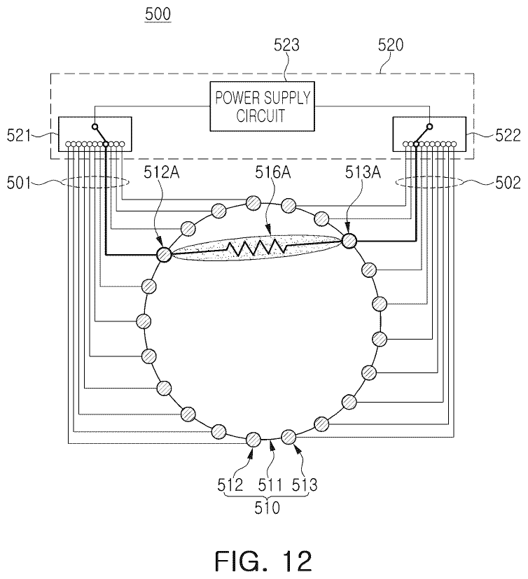

FIGS. 12 to 15 are schematic diagrams illustrating an exemplary operation of a semiconductor process apparatus according to some implementations. The semiconductor process apparatus 500 described with reference to FIGS. 12 to 15 may be similar to that previously described with reference to FIG. 11. In some implementations, the semiconductor processing device 500 may include a graphene layer 510 including a base region 511 including graphene and a plurality of pads 512 and 513 formed of a conductive material, such as metal, and a power supply 520. The graphene layer 510 may be included in a reflective layer attached to the surface of a mirror that reflects EUV light.

In FIG. 12, a first selection pad 512A is determined among the first pads 512 by a first switch circuit 521, and a second selection pad 513A among the second pads 513 may be determined by the first switch circuit 522. The bias voltage output from the power circuit 523 is applied to the first selection pad 512A and the second selection pad 513A, and heat may be generated in the selection area 516A, which is a portion of the base region 511. The selection area 516A may be selected as an area to which EUV light is not irradiated from the mirror to which the reflective layer including the graphene layer 510 is attached. By determining an area not irradiated with EUV light as a selection area 516A and applying a bias voltage to generate heat, the yield of a semiconductor process using extreme ultraviolet light may be improved by reducing the temperature imbalance in the entire area of the mirror and suppressing the occurrence of aberrations due to temperature imbalance.

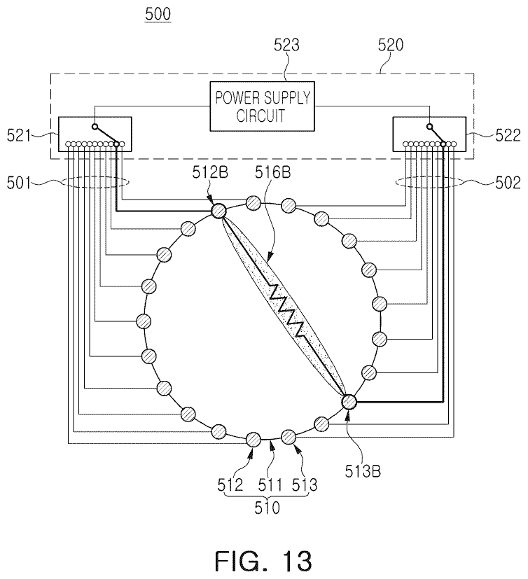

In FIG. 13, a first selection pad 512B is determined among the first pads 512 by the first switch circuit 521, and a second selection pad 513B among the second pads 513 may be determined by the first switch circuit 522. The bias voltage output from the power circuit 523 is applied to the first selection pad 512B and the second selection pad 513B. Accordingly, heat may be generated in the selection area 516B that is a portion of the base region 511. In some implementations, the selection area 516B may be different from the selection area 516A. In some implementations, the selection areas 516A and 516B may be adjusted in consideration of the pattern of EUV light irradiated to the mirror. By applying a bias voltage to the selection regions 516A and 516B in advance before the EUV light is irradiated, or by applying a bias voltage to the selection regions 516A and 516B while the EUV light is being irradiated, the temperature imbalance in the entire area of the mirror may be significantly reduced and the occurrence of aberrations may be suppressed.

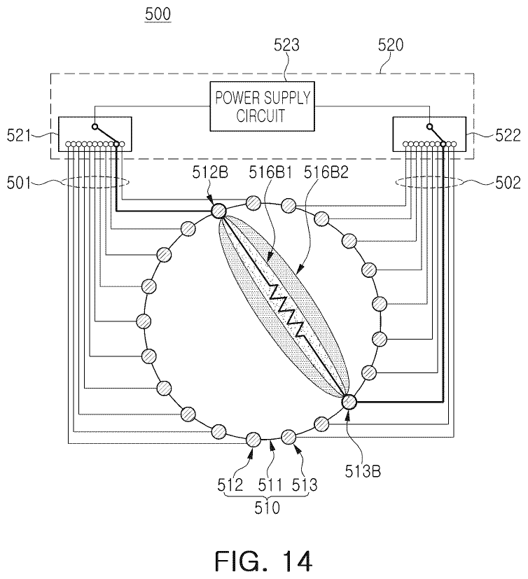

In some implementations, the area of the selected region where heat is generated by the bias voltage may be adjusted by adjusting the time for applying the bias voltage. In FIG. 14, a first selection pad 512B and a second selection pad 513B may be determined in the same manner as in the implementation described with reference to FIG. 13. However, in FIG. 14, the bias voltage output from the power circuit 523 may be applied to the first selection pad 512B and to the second selection pad 513B for a relatively longer. Accordingly, the selection region in which heat is generated by the bias voltage may extend from the first selection region 516B1 to the second selection region 516B2 as the time for applying the bias voltage elapses. However, in some implementations, the temperature of the second selection area 516B2 may be relatively lower than the temperature of the first selection area 516B1. As described above, in some implementations, the temperature of the selected region may be controlled by adjusting the time for which the bias voltage is applied, the magnitude of the bias voltage, and the like. While EUV light is being irradiated, the temperature difference by area of the mirror may be reduced and the occurrence of aberrations may be significantly reduced.

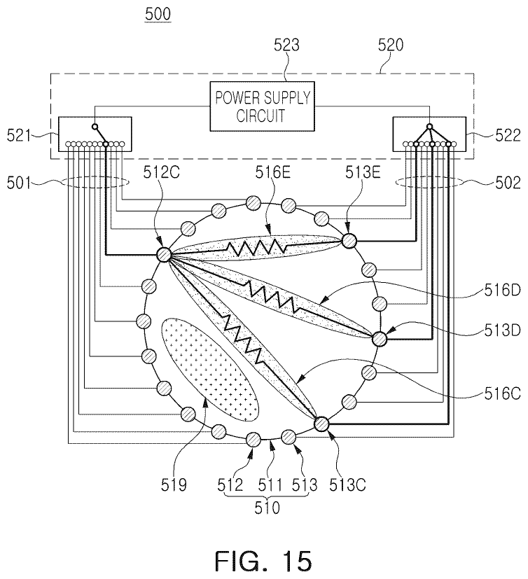

In some implementations, according to the location, area, etc. of the selected region to increase the temperature by applying the bias voltage, at least one of the first switch circuit 521 and the second switch circuit 522 may select two or more selection pads. For example, in FIG. 15, unlike the first switch circuit 521 selecting one first selection pad 512C, the second switch circuit 522 may select three second selection pads 513C, 513D, and 513E. Accordingly, in the base region 511, bias voltages are simultaneously applied to a total of three selection regions 516C, 516D, and 516E. Heat may be generated simultaneously in the selected regions 516C, 516D, and 516E.

In FIG. 15, in the mirror to which the reflective layer including the graphene layer 510 is attached, a light irradiation area 519 may be selected. EUV light irradiated to the light irradiation area 519 may be reflected to a next mirror or wafer, such that only the temperature of the light irradiation area 519 may rise locally.

In FIG. 15, by applying a bias voltage between the first selection pad 512C and the plurality of second selection pads 513C, 513D, and 513E, the temperature of an area other than the light irradiation area 519 may be increased. By suppressing the temperature imbalance of the mirror and minimizing the occurrence of aberration, the yield of the semiconductor process may be stably maintained using EUV light.

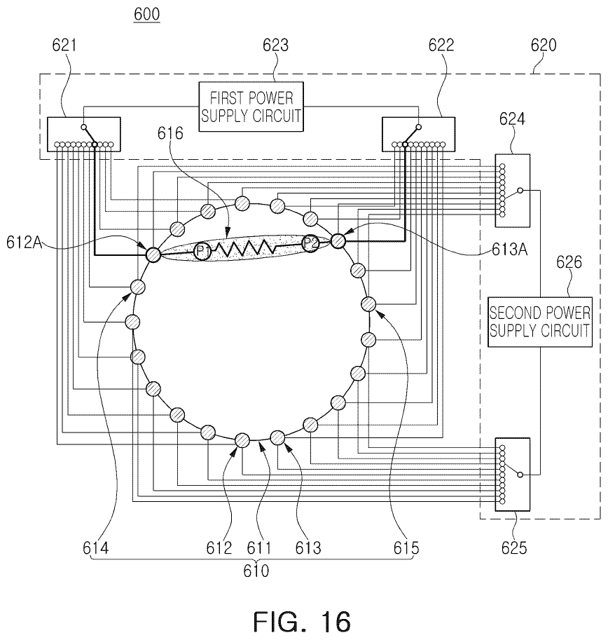

FIGS. 16 to 20 are schematic diagrams illustrating an exemplary operation of a semiconductor process apparatus according to some implementations.

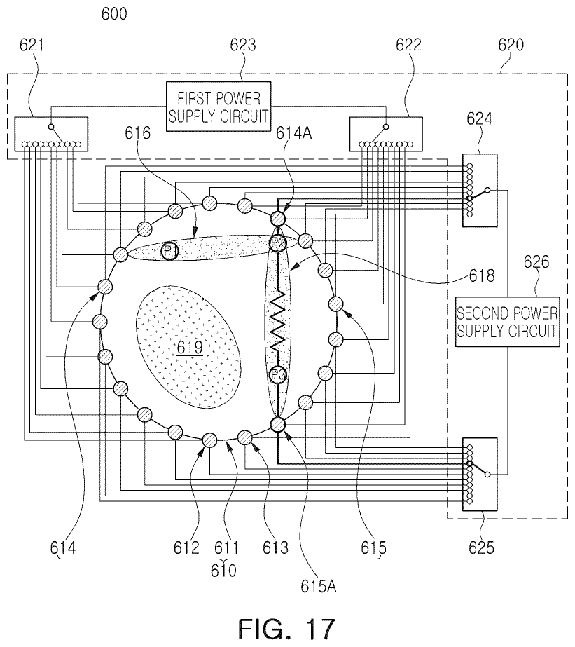

In FIGS. 16 and 17, in the semiconductor process apparatus 600, the reflective layer attached to the mirror may include a graphene layer 610, and the graphene layer 610 may include a base region 611 containing graphene and a plurality of pads 612, 613 and 614, and 615 attached to the base region 611. The plurality of pads 612, 613, 614, and 615 may be formed of a conductive material. The plurality of pads 612, 613, 614, and 615 may be divided into first pads 612, second pads 613, third pads 614, and fourth pads 615. In some implementations, the first pads 612 are pads arranged along the left edge of the base region 611, and the second pads 613 may be pads arranged along the right edge of the base region 611. In some implementations, the third pads 614 are pads arranged along the upper edge of the base region 611, and the fourth pads 615 may be pads arranged along the lower edge of the base region 611.

In FIGS. 16 and 17, the power supply 620 includes a first switch circuit 621, a second switch circuit 622, a first power supply circuit 623, a third switch circuit 624, a fourth switch circuit 625, and a second power supply circuit 626, and the like. The first switch circuit 621 is connected between the first pads 612 and the first power supply circuit 623, and the second switch circuit 622 may be connected between the second pads 613 and the first power supply circuit 623. In some implementations, the third switch circuit 624 is connected between the third pads 614 and the second power supply circuit 626, and the fourth switch circuit 625 may be connected between the fourth pads 615 and the second power supply circuit 626. Accordingly, each of the plurality of pads 612, 613, 614, and 615 may be connected in common to two of the first switch circuit 621, the second switch circuit 622, the third switch circuit 624, and the fourth switch circuit 625.

In FIGS. 16 and 17, by setting the timing at which the first power supply circuit 623 and the second power supply circuit 626 output bias voltages differently, temperatures of the first to third points P1 to P3 may be differently controlled. In FIG. 16, the first switch circuit 621 may be configured to select a first selection pad 612A from among the first pads 612, and the second switch circuit 622 may be configured to select the second selection pad 613A from among the second pads 613. Each of the third switch circuit 624 and the fourth switch circuit 625 may be turned off so that a selection pad among the third pads 614 and the fourth pads 615 may not be selected. The first bias voltage output from the first power supply circuit 623 may be applied to the first selection region 616 between the first selection pad 612A and the second selection pad 613A. Accordingly, the temperatures of the first point P1 and the second point P2 included in the first selection region 616 may also rise.

In FIG. 17, the first switch circuit 621 and the second switch circuit 622 are turned off, the third switch circuit 624 may be configured to select the first selection pad 614A from among the third pads 614, and the fourth switch circuit 625 may be configured to select the second selection pad 615A from among the fourth pads 615. Accordingly, the second bias voltage output from the second power supply circuit 626 is applied to the second selection region 618, and the temperature of the second point P2 and the third point P3 may rise.

A light irradiation area 619 where EUV light is irradiated onto the mirror to which the reflective layer including the graphene layer 610 is attached may be defined as illustrated in FIG. 17. To increase the temperature of the area other than the light irradiation area 619, as described with reference to FIGS. 16 and 17, the bias voltage is sequentially applied to the first selection region 616 and the second selection region 618, and the temperature imbalance of the mirror may be resolved.

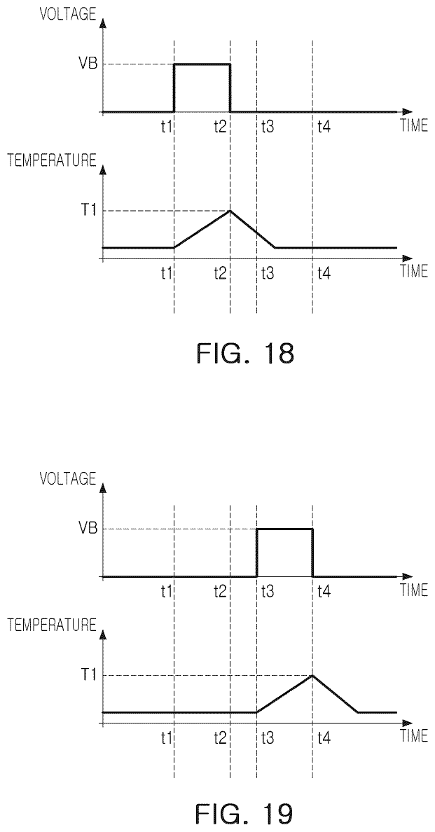

FIGS. 18 to 20 are timing diagrams illustrating an exemplary operation of the semiconductor process apparatus 600 illustrated in FIGS. 16 and 17. FIG. 18 is a diagram illustrating an exemplary operation of the first power supply circuit 623 and the resulting change in temperature of the base region 611. In FIG. 18, between the first time point t1 and the second time point t2, a first bias voltage VB may be applied to the first selection region 616. Accordingly, the temperature of the first point P1 included in the first selection region 616 may rise to the first temperature T1.

FIG. 19 is a diagram illustrating an exemplary operation of the second power supply circuit 626 and the temperature change of the base region 611 according to the operation. In FIG. 19, between the third time point t3 and the fourth time point t4, the second bias voltage VB may be applied to the second selection region 618. Accordingly, the temperature of the third point P3 included in the second selection region 618 may rise to the first temperature T1. The second bias voltage VB output from the second power supply circuit 626 may have the same level as the first bias voltage VB output from the first power supply circuit 623.

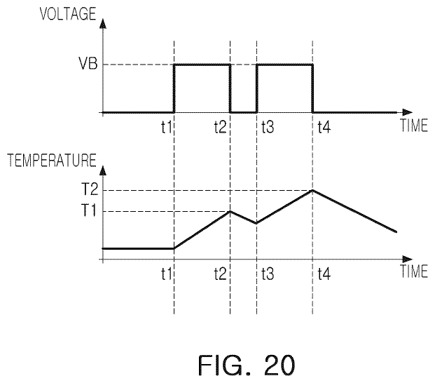

With reference to FIGS. 16 and 17, the exemplary operation shown in FIG. 18 and the exemplary operation shown in FIG. 19 may be continuously executed. In FIG. 20, a first bias voltage VB is applied to the first selection region 616 between the first time point t1 and the second time point t2, and between the third time point t3 and the fourth time point t4, the second bias voltage VB may be applied to the second selection region 618.

The temperature of the second point P2 overlapping the first selection region 616 and the second selection region 618 increases to the first temperature T1 at the second time point t2, and from the third point in time t3, the temperature may be increased again by the second bias voltage to reach the second temperature T2. As described above, in the semiconductor process apparatus 600, the timing at which each of the first power supply circuit 623 and the second power supply circuit 626 applies the bias voltage is controlled, and temperatures of various points P1-P3 defined in the base region 611 may be set differently.

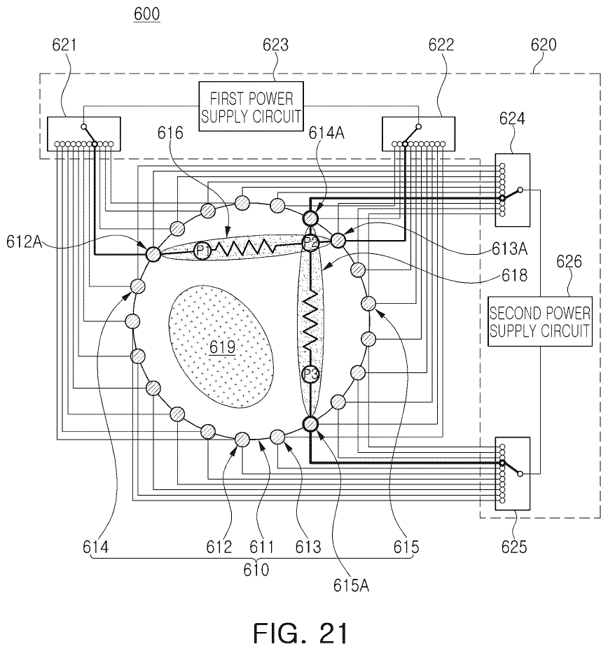

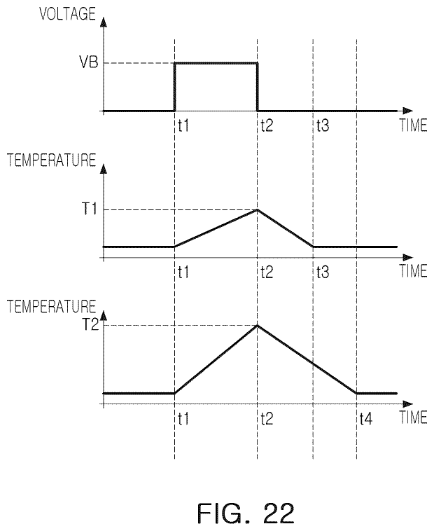

FIGS. 21 and 22 are schematic diagrams illustrating an exemplary operation of a semiconductor process apparatus according to some implementations. In FIGS. 21 and 22, a configuration of the semiconductor process apparatus 600 may be the same as described above with reference to FIGS. 16 and 17. However, in FIGS. 21 and 22, to increase the temperature of the area other than the light irradiation area 619, a bias voltage may be simultaneously applied to the first selection pad 612A, the second selection pad 613A, the third selection pad 614A, and the fourth selection pad 615A. In some implementations, each of the first power supply circuit 623 and the second power supply circuit 626 may be configured to output the bias voltage VB during the time from the first time point t1 to the second time point t2, as illustrated in FIG. 22. Accordingly, a bias voltage is simultaneously applied to the first selection pad 612A, the second selection pad 613A, the third selection pad 614A, and the fourth selection pad 615A, and temperatures of the first selection region 616 and the second selection region 618 may increase.

The temperature graph of FIG. 22 shows a graph illustrating temperatures of a first point P1 included in the first selection area 616, a second point P2 overlapping the first selection area 616 and the second selection area 618, and a third point P3 included in the second selection area 618. Temperatures of the first point P1 and the third point P3 may increase up to the first temperature T1 by the bias voltage. In some implementations, the temperature of the second point P2 overlapping both the first selection area 616 and the second selection area 618 may increase up to the second temperature T2 by the bias voltage output from each of the first power supply circuit 623 and the second power supply circuit 626.

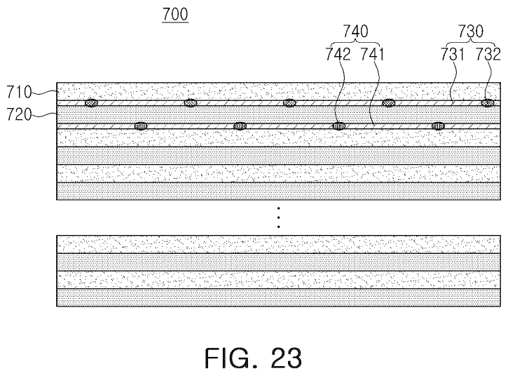

FIG. 23 is a schematic diagram illustrating an exemplary stacked structure of a reflective layer included in a mirror in a semiconductor process apparatus according to some implementations. In FIG. 23, the reflective layer 700 included in the mirror may include a plurality of silicon layers 710, a plurality of molybdenum layers 720, and a plurality of graphene layers 730 and 740. The arrangement and thickness of the plurality of silicon layers 710, the plurality of molybdenum layers 720, and the plurality of graphene layers 730 and 740 will be understood with reference to the descriptions of FIGS. 5 to 9.

In FIG. 23, the first graphene layer 730 may include a base region 731 formed of graphene and a plurality of pads 732 attached to the base region 731. In some implementations, the second graphene layer 740 may also include a base region 741 and a plurality of pads 742. As illustrated in FIG. 23, the positions where the plurality of pads 732 are attached to the base region 731 in the first graphene layer 730 may be different from positions of the plurality of pads 742 attached to the base region 741 in the second graphene layer 740. The plurality of pads 732 included in the first graphene layer 730 and the plurality of pads 742 included in the second graphene layer 740 may be connected to different power supplies. Accordingly, in the first graphene layer 730, the selected region where the bias voltage is applied and heat is generated may be determined as a location different from the selected area where heat is generated by applying a bias voltage in the second graphene layer 740, and a different shape and the like. According to the position and area of the light irradiation area where the EUV light is irradiated to the mirror to which the reflective layer 700 is attached, by appropriately selecting selection areas in each of the first graphene layer 730 and the second graphene layer 740, the temperature imbalance of the mirror may be significantly reduced and the generation of aberration may be suppressed.

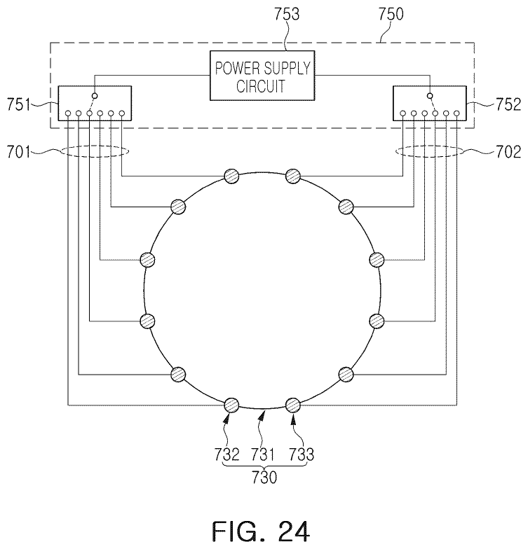

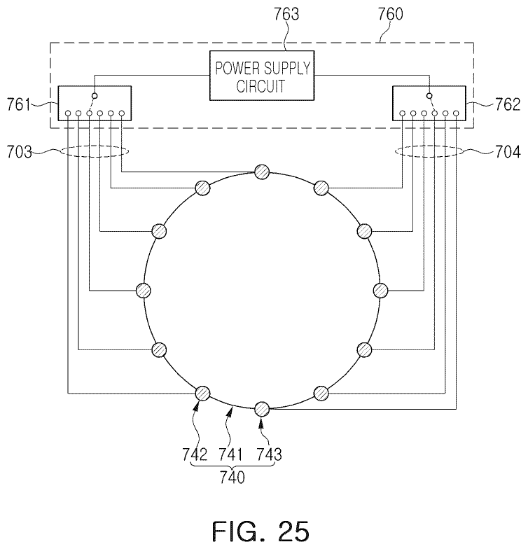

FIGS. 24 and 25 are schematic diagrams illustrating an exemplary operation of a semiconductor process apparatus according to some implementations. In FIG. 24, the first graphene layer 730 is connected to the first power supply 750. The first graphene layer 730 includes a base region 731 and a plurality of pads 732 and 733, and the first power supply 750 may include a first switch circuit 751, a second switch circuit 752, and a power circuit 753. The first switch circuit 751 is connected to the plurality of first pads 732 through the plurality of first wires 701, and the second switch circuit 752 may be connected to the plurality of second pads 733 through the plurality of second wires 702.

In FIG. 25, the second graphene layer 740 may be connected to the second power supply 760. In some implementations, the second graphene layer 740 includes a base region 741 and a plurality of pads 742 and 743, and the second power supply 760 may include a first switch circuit 761, a second switch circuit 762, and a power circuit 763. The first switch circuit 761 is connected to the plurality of first pads 742 through the plurality of first wires 703, and the second switch circuit 762 may be connected to the plurality of second pads 743 through the plurality of second wires 704.

In FIGS. 24 and 25, the positions where the plurality of pads 732 and 733 are disposed in the first graphene layer 730, and positions of the plurality of pads 742 and 743 in the second graphene layer 740, may be different from each other. Accordingly, the selected region where heat is generated in the first graphene layer 730 by the first power supply 750 may be set differently from the selected area where heat is generated in the second graphene layer 740 by the second power supply 760. By variously setting and combining the selection area of the first graphene layer 730 and the selection area of the second graphene layer 740, in the mirror to which the reflective layer 700 is attached, the temperature of the area other than the light irradiation area where EUV light is irradiated may be effectively increased. Accordingly, temperature imbalance and consequent aberration, which may occur while EUV light is irradiated to the mirror to which the reflective layer 700 is attached, may be suppressed, and the yield of a semiconductor process using extreme ultraviolet light may be stably managed.

As set forth above, according to some implementations, a reflective layer included in at least one of a plurality of mirrors included in a semiconductor process apparatus may include a graphene layer. The graphene layer has a relatively high thermal conductivity compared to other layers included in the reflective layer, and thus, temperature imbalance generated in the mirror may be alleviated by the graphene layer. In addition, according to some implementations, by applying a voltage to the graphene layer to increase the temperature of at least a portion of the graphene layer, the temperature imbalance generated in the mirror may be reduced and the yield of the semiconductor process may be improved.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

What is claimed is:

1. A semiconductor process apparatus comprising:
a light generator configured to output extreme ultraviolet (EUV) light having an EUV wavelength band;
a mask stage configured to seat a mask, the mask being configured to reflect the EUV light output from the light generator;
an optical light receiver including a plurality of mirrors that are configured to generate output light by reflecting the EUV light reflected from the mask, at least one of the plurality of mirrors including a mirror body and a reflective layer attached to a surface of the mirror body;
a power supply configured to apply a bias voltage to the reflective layer; and
a substrate stage configured to seat a substrate to be irradiated with the output light,
wherein the reflective layer includes a plurality of silicon layers, a plurality of molybdenum layers alternately stacked with the plurality of silicon layers, and at least one graphene layer, and
wherein the at least one graphene layer includes:
a base region including graphene, and
a plurality of pads attached to the base region and configured to enable the bias voltage to be applied to the plurality of pads.

2. The semiconductor process apparatus of claim 1, wherein the plurality of pads are arranged along an edge of the base region.

3. The semiconductor process apparatus of claim 1, wherein the power supply includes:
a first power supply circuit configured to output a first bias voltage,
a first switch circuit connected between first pads of the plurality of pads and the first power supply circuit, and
a second switch circuit connected between second pads of the plurality of pads and the first power supply circuit, the second pads being different from the first pads.

4. The semiconductor process apparatus of claim 3,
wherein the first switch circuit includes a first multiplexer, and
wherein the second switch circuit includes a second multiplexer.

5. The semiconductor process apparatus of claim 3,
wherein the first switch circuit is configured to determine a first selection pad among the first pads,
wherein the second switch circuit is configured to determine a second selection pad among the second pads, and
wherein the first power supply circuit is configured to apply the first bias voltage to the first selection pad and the second selection pad.

6. The semiconductor process apparatus of claim 5, wherein the first switch circuit and the second switch circuit are configured to determine the first selection pad and the second selection pad based on a location and an area of an irradiation area in which the EUV light is irradiated in at least one mirror of the plurality of mirrors.

7. The semiconductor process apparatus of claim 3, wherein the power supply further includes:
a second power supply circuit configured to output a second bias voltage,
a third switch circuit connected between third pads of the plurality of pads and the second power supply circuit, and
a fourth switch circuit connected between fourth pads of the plurality of pads and the second power supply circuit, the fourth pads being different from the third pads.

8. The semiconductor process apparatus of claim 7,
wherein the first switch circuit is configured to determine a first selection pad among the first pads,
wherein the second switch circuit is configured to determine a second selection pad among the second pads,
wherein the third switch circuit is configured to determine a third selection pad among the third pads, and
wherein the second switch circuit is configured to determine a fourth selection pad among the fourth pads,
wherein the first power supply circuit is configured to apply a first bias voltage to the first selection pad and the second selection pad for a first time period, and
wherein the second power supply circuit is configured to apply a second bias voltage to the third selection pad and the fourth selection pad for a second time period after the first time period.

9. A semiconductor process apparatus comprising:
a mask stage configured to seat a mask;
a substrate stage configured to seat a substrate;
a light generator configured to output extreme ultraviolet light (EUV) having an extreme ultraviolet EUV wavelength band to the mask; and
an optical light receiver including a plurality of mirrors configured to reflect the EUV light reflected from the mask and enable the EUV light to be incident to the substrate, at least one of the plurality of mirrors including a mirror body and a reflective layer attached to a surface of the mirror body,
wherein the reflective layer includes a plurality of silicon layers, a plurality of molybdenum layers alternately stacked with the plurality of silicon layers, and at least one graphene layer.

10. The semiconductor process apparatus of claim 9, wherein a thickness of the graphene layer is less than a thickness of each of the plurality of silicon layers and the plurality of molybdenum layers.

11. The semiconductor process apparatus of claim 9, wherein the reflective layer further includes a plurality of metal layers disposed between the plurality of silicon layers and the plurality of molybdenum layers.

12. The semiconductor process apparatus of claim 11, wherein the plurality of metal layers include:
at least one first metal layer including yttrium or niobium, and
at least one second metal layer including ruthenium.

13. The semiconductor process apparatus of claim 11,
wherein the graphene layer includes a first surface and a second surface parallel to the first surface,
wherein the first surface is in contact with one of the plurality of silicon layers and the plurality of molybdenum layers, and
wherein the second surface is in contact with at least one of the plurality of metal layers.

14. The semiconductor process apparatus of claim 9,
wherein the graphene layer includes a first surface and a second surface parallel to the first surface,
wherein the first surface is in contact with one of the plurality of silicon layers, and
wherein the second surface is in contact with one of the plurality of molybdenum layers.

15. The semiconductor process apparatus of claim 9,
wherein the graphene layer includes a first surface and a second surface parallel to the first surface,
wherein the first surface is a surface exposed externally, and
wherein the second surface contacts one of the plurality of silicon layers and the plurality of molybdenum layers.

16. The semiconductor process apparatus of claim 9,
wherein the graphene layer includes a first surface and a second surface parallel to the first surface,
wherein the first surface is in contact with one of the plurality of silicon layers and the plurality of molybdenum layers, and
wherein the second surface is in contact with one surface of the mirror body.

17. The semiconductor process apparatus of claim 9,
wherein the graphene layer includes a first graphene layer and a second graphene layer,
wherein each of the first graphene layer and the second graphene layer includes a first surface and a second surface parallel to the first surface,
wherein, in each of the first graphene layer and the second graphene layer, the first surface is located farther from the mirror body than the second surface,
wherein the first surface of the first graphene layer is in contact with a first silicon layer of the plurality of silicon layers, and
wherein the second surface of the first graphene layer is in contact with a first molybdenum layer of the plurality of molybdenum layers.

18. The semiconductor process apparatus of claim 17,
wherein the first surface of the second graphene layer is in contact with a second molybdenum layer of the plurality of molybdenum layers,
wherein the second surface of the second graphene layer is in contact with a second silicon layer of the plurality of silicon layers, and
wherein the first molybdenum layer is the same molybdenum layer as the second molybdenum layer.

19. A semiconductor process apparatus comprising:
a light generator configured to output extreme ultraviolet (EUV) light;
a mask stage configured to seat a mask, the mask being configured to reflect the EUV light output from the light generator;
a substrate stage configured to seat a substrate, the substrate being configured to receive the EUV light reflected from the mask; and
an optical light receiver disposed between the mask stage and the substrate stage and including a plurality of mirrors reflecting the EUV light reflected from the mask,
wherein at least one of the plurality of mirrors includes a mirror body and a reflective layer attached to a surface of the mirror body,
wherein the reflective layer includes a plurality of first layers, a plurality of second layers, and at least one third layer,
wherein the plurality of first layers has a first material, the plurality of second layers having a second material, and the third layer has a third material,
wherein the first material, the second material, and the third material are different from each other,
wherein the plurality of first layers and the plurality of second layers are alternately stacked, and
wherein a thickness of the third layer is less than a thickness of each of the plurality of first layers and the plurality of second layers.

20. The semiconductor process apparatus of claim 19, wherein thermal conductivity of a material constituting the third layer is higher than thermal conductivity of a material constituting the plurality of first layers and thermal conductivity of a material constituting the plurality of second layers.
